(19) United States
(12) Patent Application Publication
(10) Pub. No.: US 2025/0107046 A1
(43) Pub. Date: Mar. 27, 2025

(54) SYSTEMS AND METHODS FOR THERMAL MANAGEMENT OF ELECTRONIC DEVICES

(71) Applicant: Microsoft Technology Licensing, LLC, Redmond, WA (US)

(72) Inventors: Kathryn M. OSEEN-SENDA, Seattle, WA (US); Dennis TRIEU, Calgary (CA); Oscar FARIAS MOGUEL, Seattle, WA (US); Martha Geoghegan PETERSON, Woodinville, WA (US); Alexis Grace SCHUBERT, Seattle, WA (US)

(21) Appl. No.: 18/473,795

(22) Filed: Sep. 25, 2023

(51) Int. Cl. H05K 7/20; G06F 1/20

(52) U.S. Cl. CPC H05K 7/2039; G06F 1/206; H05K 7/20254; H05K 7/20263; H05K 7/20272; H05K 7/20318; H05K 7/20327

(57) ABSTRACT

A device may include a heat sink body defining a fluid reservoir. A device may include a working fluid in the fluid reservoir. A device may include a movable contact surface configured to transfer heat from a heat-generating component to the working fluid, wherein at least a portion of the movable contact surface is movable relative to the heat sink body.

### BACKGROUND

### Background and Relevant Art

Computing devices can generate a large amount of heat during use. The computing components can be susceptible to damage from the heat and commonly require cooling systems to maintain the component temperatures in a safe range during heavy processing or usage loads. Different computing demands and applications produce different amounts of thermal energy and require different amounts of thermal management.

### BRIEF SUMMARY

In some aspects, the techniques described herein relate to a thermal management device, including: a heat sink body defining a fluid reservoir; a working fluid in the fluid reservoir; and a movable contact surface configured to transfer heat from a heat-generating component to the working fluid, wherein at least a portion of the movable contact surface is movable relative to the heat sink body.

In some aspects, the techniques described herein relate to a thermal management system including: a thermal management device including: a heat sink body defining a fluid reservoir, a single-phase working fluid in the fluid reservoir, and a movable contact surface configured to transfer heat from a heat-generating component to the single-phase working fluid, wherein at least a portion of the movable contact surface is movable relative to the heat sink body; and a heat exchanger in fluid communication with the fluid reservoir and configured to exhaust heat from the single-phase working fluid.

In some aspects, the techniques described herein relate to a thermal management system including: a thermal management device including: a heat sink body defining a fluid reservoir, a dual-phase working fluid in the fluid reservoir, and a movable contact surface configured to transfer heat from a heat-generating component to the dual-phase working fluid, wherein at least a portion of the movable contact surface is movable relative to the heat sink body; and a condenser in fluid communication with the fluid reservoir and configured to exhaust heat from the dual-phase working fluid.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1-1 is a side view of a thermal management device with a movable contact surface, according to at least one embodiment of the present disclosure.

FIG. 1-2 is a side cross-sectional view of the embodiment of the thermal management device 100 of FIG. 1-1.

FIG. 1-3 is a side cross-sectional view of the embodiment of the thermal management device 100 of FIG. 1-1 in contact with a heat-generating component.

FIG. 2 is a side cross-sectional view of a thermal management device with a single-phase working fluid therein, according to at least one embodiment of the present disclosure.

FIG. 3 is a side cross-sectional view of a thermal management device with a plurality of fluid ports to flow single-phase working fluid into and out of the fluid reservoir, according to at least one embodiment of the present disclosure.

FIG. 4 is a side cross-sectional view of a thermal management device with a plurality of fluid ports to flow dual-phase working fluid into and out of the fluid reservoir, according to at least one embodiment of the present disclosure.

FIG. 5 is a side cross-sectional view of a thermal management device with a plurality of fluid ports to flow dual-phase working fluid into and out of the fluid reservoir in a vertical orientation relative to gravity, according to at least one embodiment of the present disclosure.

FIG. 6 is a side cross-sectional view of a thermal management device with a flexible contact surface, according to at least one embodiment of the present disclosure.

FIG. 7 is a side cross-sectional view of an embodiment of a thermal management device with an elastically deformable heat sink body and a dual-phase working fluid therein.

### DETAILED DESCRIPTION

The present disclosure relates generally to systems and methods for thermal management of electronic devices or other heat-generating components. More particularly, embodiments according to the present disclosure relate to thermal management and thermal management devices for processors, hardware storage devices, application specific integrated circuits (ASICs), power supplies, system-on-chips (SOCs), networking devices, and other heat-generating components with non-planar surfaces. In an example, a SOC has multiple processors, memory devices, and electronic components facilitating communication between the processors and memory devices. The SOC may have a varying topography across the surfaces of the processors, memory devices, and other electronic components limiting the applicability of conventional heat sinks and thermal management devices.

In some embodiments, a thermal management device according to the present disclosure includes a contact surface configured to conform to a surface of the heat-generating component. The thermal management device includes a flexible contact surface, a plurality of independently moveable segments of the contact surface, or combinations thereof. In some embodiments, the thermal management device includes a plurality of contact surface segments that are independently movable relative to a heat sink. In some embodiments, at least one of the contact surface segments is coupled to a flexible heat transfer element to transfer heat from the contact surface segment to the heat sink of the thermal management device.

In some embodiments, the thermal management device includes a flexible contact surface that allows the contact surface to plastically and/or elastically deform to the topography of the heat-generating component(s) and receive heat from the plurality of surfaces of the heat-generating component(s). In some embodiments, the flexible contact surface includes or is made of a polymer or metal sheet, such as a mylar sheet. The flexible contact surface allows the contact surface to conform to a surface of the heat-generating component and receive heat from the heat-generating. In some embodiments, the flexible contact surface allows the contact surface to conform to a non-planar surface of the heat-generating component and/or a plurality of surfaces of the heat-generating component, providing thermal communication between a greater variety of heat-generating components and a heat sink of the thermal management device.

In some embodiments, the heat sink includes one or more heat exchange features. In some embodiments, a heat exchange feature includes a solid-state heat exchange feature that exhausts heat to ambient fluid, such as air. A solid-state heat exchange feature may include a fin, rod, pin, heat pipe, surface feature or coating, or other structure that increases surface area of the heat sink to more readily exhaust heat. In some embodiments, the heat exchange feature includes a reservoir or volume of working fluid that exhausts heat from the heat sink to ambient air. In some embodiments, the heat exchange feature includes a reservoir or volume of working fluid that is connected to an external heat exchanger through one or more fluid conduits. In some embodiments, the working fluid is a single-phase working fluid that remains in a single phase throughout the operation of the thermal management device (such as a liquid phase). In some embodiments, the working fluid is a dual-phase working fluid that vaporizes and condenses during operation of the thermal management device to transfer heat through the latent heat of boiling. In some embodiments, the working fluid is a fluorocarbon based working fluid. In some embodiments, the working fluid is a hydrocarbon based working fluid. In some embodiments, the working fluid is conveyed from a reservoir or other volume of the heat sink to an external heat exchanger that cools and/or condenses the working fluid before returning the working fluid to the reservoir or other volume of the heat sink.

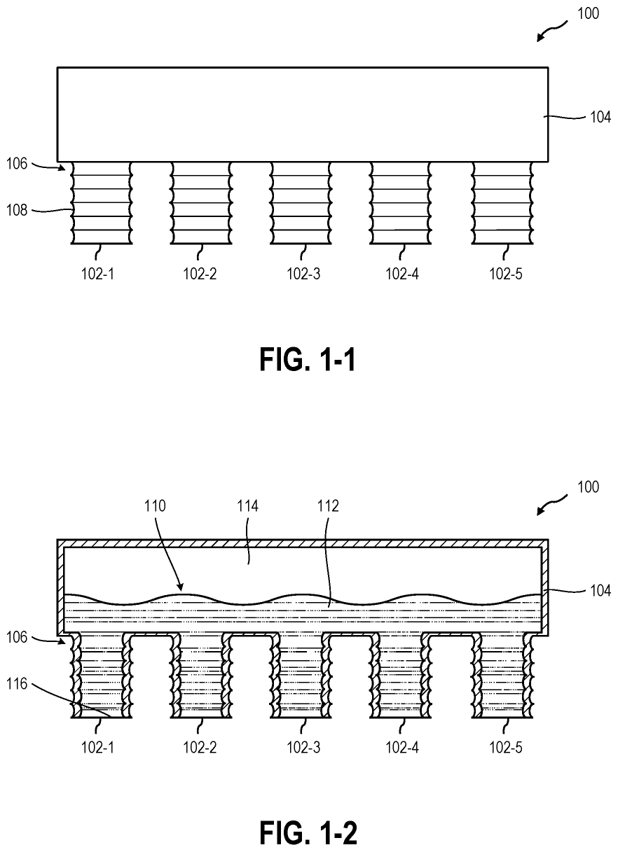

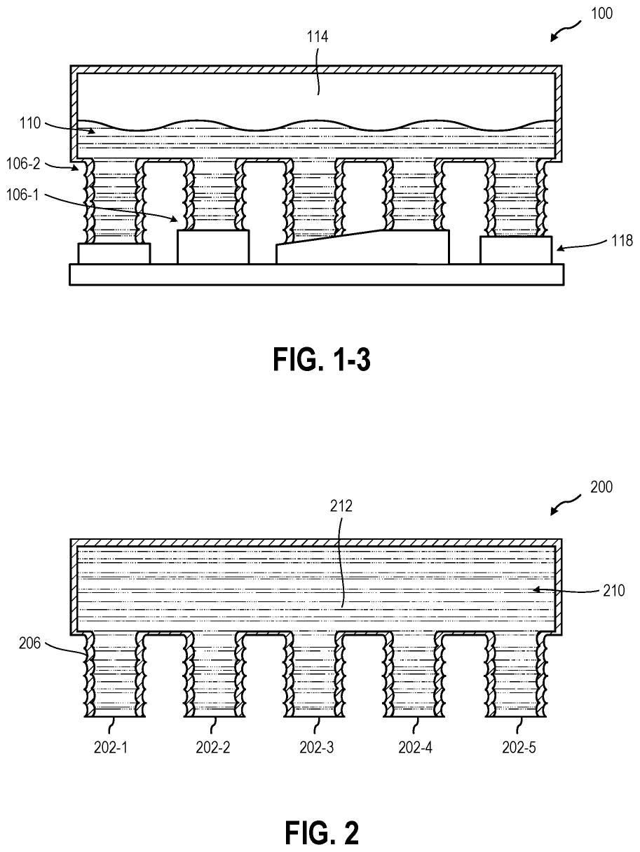

FIG. 1-1 is a side view of an embodiment of a thermal management device 100 including a plurality of contact surface segments 102-1, 102-2, 102-3, 102-4, 102-5 that are independently movable relative to a heat sink body 104. In some embodiments, at least one contact surface segment 102-1 is connected to the body 104 by a flexible support element 106.

In some embodiments, the flexible support element 106 is or includes a bellows. In some embodiments, the bellows is a metal bellows. In some embodiments, the bellows is a polymer bellows. In some embodiments, the flexible support element 106 includes a plurality of convolutions 108 that allow the flexible support element 106 to extend or contract in a direction between the contact surface segment 102-1 and the heat sink body 104. In some embodiments, the bellows includes edge-welded bellows. In some embodiments, the flexible support element 106 allows the contact surface segment 102-1 to change orientation relative to an initial position. For example, the flexible support element 106 allows the contact surface segment 102-1 to rotate relative to an initial position when the flexible support element 106 elastically and/or plastically deforms.

In some embodiments, elastic deformation of the flexible support element 106 allows the flexible support element 106 to return or restore toward or to an original position for reuse of thermal management device 100. In some embodiments, elastic deformation can continue to provide a compressive force between the contact surface segment and the heat-generating component, ensuring a reliable thermal connection between the contact surface and the heat-generating component. For example, during use or transportation of the system of device containing the heat-generating component, the movement or vibrations of the heat-generating component and thermal management device relative to one another may introduce a gap between the contact surface and the heat-generating component. An elastically deformed flexible support element 106 may apply a continuous compressive force to the contact surface segment 102-1 to maintain the thermal connection.

In some embodiments, the plastic deformation of the flexible support element 106 allows the flexible support element 106 to retain a position of the contact surface segment 102-1 upon removal of the thermal management device 100 from the heat-generating component, for example, for maintenance, repair, or replacement of one or more components. In some embodiments, the plastic deformation of the flexible support element 106 allows the contact surface segment 102-1 to establish a thermal connection to the heat-generating component, and maintain that thermal connection, without continuous force applied to the heat-generating component. For example, plastic deformation allows the thermal management device 100 to be applied to the heat-generating component at initial installation with only an initial application of force to the sensitive parts of the heat-generating component. In some embodiments, the flexible support element 106 exhibits both plastic and elastic deformation during installation and use with the heat-generating component.

FIG. 1-2 is a side cross-sectional view of the embodiment of the thermal management device 100 of FIG. 1-1. In some embodiments, the heat sink includes a fluid reservoir 110 in the heat sink body 104. In some embodiments, the fluid reservoir 110 has a working fluid 112 therein. In some embodiments, the working fluid 112 has a liquid phase in the fluid reservoir 110. In some embodiments, the working fluid 112 has a vapor phase in the fluid reservoir 110. In some embodiments, the working fluid 112 is positioned at least partially in the flexible support element 106. The working fluid 112 receives heat from a heat-generating component through the contact surface (including the contact surface segments 102-1, 102-2, 102-3, 102-4, 102-5) to the heat sink body 104 and/or through the thermal management device 100.

In some embodiments, the working fluid 112 is a single-phase working fluid that remains in a single phase throughout the operation of the thermal management device (such as a liquid phase).

In some embodiments, the fluid reservoir 110 includes a headspace 114 in which a vapor phase of the working fluid 112 or other gas is present. In some embodiments, the working fluid 112 is a dual-phase working fluid that receives heat from the contact surface (e.g., the contact surface segments 102-1, 102-2, 102-3, 102-4, 102-5) and vaporizes to carry heat away from the contact surface into the fluid reservoir 110. In some embodiments, the latent heat of boiling allows the working fluid 112 to absorb heat and vaporize without substantially increasing in temperature.

In some embodiments, the working fluid 112 has a boiling temperature below a critical temperature at which the heat-generating components experience thermal damage. The working fluid 112 can thereby receive heat from the heat-generating components to cool the heat-generating components before the heat-generating components experience damage.

For example, the heat-generating components may be computing components that experience damage above 100° Celsius (C). In some embodiments, the boiling temperature of the working fluid 112 is less than a critical temperature of the heat-generating components. In some embodiments, the boiling temperature of the working fluid 112 is less about 90° C. at 1 atmosphere of pressure. In some embodiments, the boiling temperature of the working fluid 112 is less about 80° C. at 1 atmosphere of pressure. In some embodiments, the boiling temperature of the working fluid 112 is less about 70° C. at 1 atmosphere of pressure. In some embodiments, the boiling temperature of the working fluid 112 is less about 60° C. at 1 atmosphere of pressure. In some embodiments, the boiling temperature of the working fluid 112 is at least about 35° C. at 1 atmosphere of pressure. In some embodiments, the working fluid 112 includes water. In some embodiments, the boiling temperature of the working fluid 112 is any of the above at more or less than 1 atmosphere of pressure.

In some embodiments, the working fluid 112 includes glycol. In some embodiments, the working fluid 112 includes a combination of water and glycol. In some embodiments, the working fluid 112 includes an aqueous solution. In some embodiments, the working fluid 112 includes an electronic liquid, such as FC-72 available from 3M, or similar non-conductive fluids.

In some embodiments, an interior surface 116 of the contact surface (e.g., the contact surface segments 102-1, 102-2, 102-3, 102-4, 102-5) and/or an interior surface of the flexible support element 106 have nucleation sites thereon that promote the nucleation of vapor bubbles of the working fluid 112 at or above the boiling temperature of the working fluid 112.

FIG. 1-3 is a side cross-sectional view of the embodiment of the thermal management device 100 of FIG. 1-1 with the contact surface conforming to the topography of a heat-generating component 118 or heat-generating components to which the thermal management device 100 is connected. In some embodiments, the movement of the flexible support elements 106 compresses the headspace 114 and a compressible gas therein, which increases a pressure inside the headspace 114 and the fluid reservoir 110. In some embodiments, movement of a first flexible support element 106-1 relative to the heat sink body 104 (e.g., compression that reduces an interior volume thereof) is at least partially compensated for by a movement of a second flexible support element 106-2 relative to the heat sink body 104 (e.g., extension that increases an interior volume thereof).

FIG. 2 is a side cross-sectional view of an embodiment of a thermal management device 200 with a single-phase working fluid 212 therein without a headspace. While some embodiments of a thermal management device including a single-phase working fluid 212 have a headspace, a single-phase working fluid 212 may not need a headspace, as the working fluid 212 does not boil and increase pressure inside the fluid reservoir 210. In some embodiments, without a headspace in the fluid reservoir and/or when the fluid reservoir 210 is substantially filled with a liquid phase of the working fluid 212, the thermal management device 200 is operably in any orientation relative to gravity without a portion of the contact surface (e.g., contact surface segments 202-1, 202-2, 202-3, 202-4, 202-5) not contacting the liquid phase of the working fluid 212. While a vapor phase of the working fluid 212 or other gas in the fluid reservoir 210 may receive and/or conduct heat from the contact surface, a liquid phase or liquid working fluid 212 absorbs heat from the contact surface more efficiently.

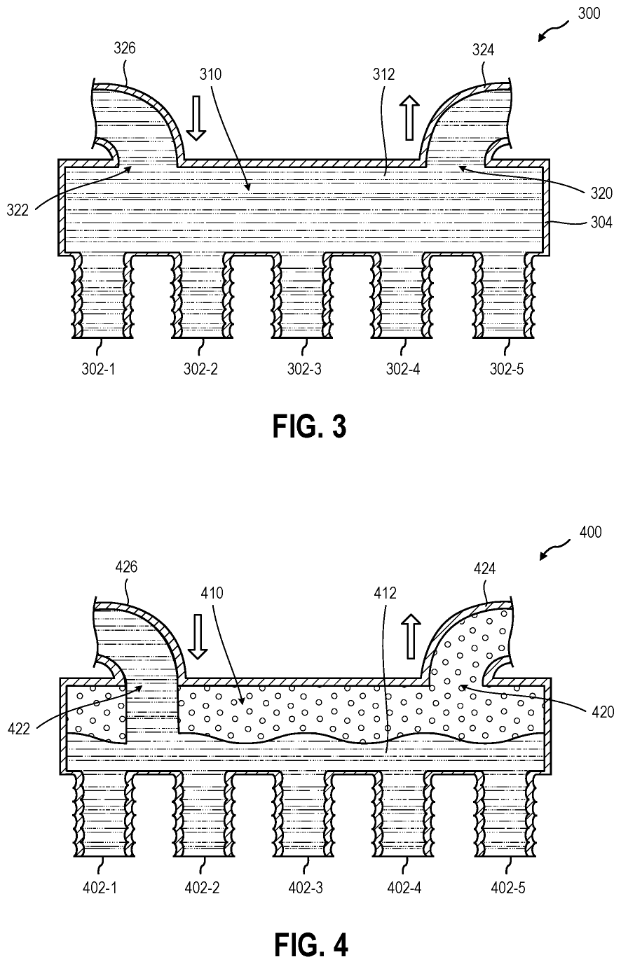

While the embodiments described in relation to FIG. 1-1 through FIG. 2 include a sealed fluid reservoir in the heat sink body and the flexible support elements, in some embodiments, the heat sink body includes one or more ports to flow at least a portion of the working fluid from the fluid reservoir to an external heat exchanger or condenser. Referring now to FIG. 3, in some embodiments, a thermal management device 300 includes a heat sink body 304 with an outlet port 320 and an inlet port 322 that allow fluid communication out of and into the fluid reservoir 310, respectively. In some embodiments, a single port allows movement of the working fluid 312 in and out of the fluid reservoir 310.

In some embodiments, the outlet port 320 is connected to an outlet conduit 324 that allows fluid flow therethrough to a heat exchanger to exhaust heat from the single-phase working fluid 312. In some embodiments, the inlet port 322 is connected on an inlet conduit 326 that allows fluid flow therethrough from a heat exchanger to return cooled single-phase working fluid 312 to the fluid reservoir 310. By receiving heat from a movable contact surface (e.g., contact surface segments 302-1, 302-2, 302-3, 302-4, 302-5) and allowing the flow of hot working fluid 312 to an external or remote heat exchanger, a thermal management device 300 can allow liquid cold plate cooling to a heat-generating component or plurality of heat-generating components with a varying topography with only a single thermal management device.

Referring now to FIG. 4, in some embodiments, a thermal management device 400 includes a heat sink body 404 with an outlet port 420 and an inlet port 422 that allow fluid communication out of and into the fluid reservoir 410, respectively. In some embodiments, a single port allows movement of the working fluid 412 in and out of the fluid reservoir 410.

In some embodiments, the outlet port 420 is connected to an outlet conduit 424 that allows a vapor phase of the working fluid 412 to flow therethrough to a condenser to exhaust heat from the dual-phase working fluid 412. In some embodiments, the inlet port 422 is connected on an inlet conduit 426 that allows flow of a condensate of the working fluid 412 therethrough from the condenser to return the liquid phase of the working fluid 412 to the fluid reservoir 410. By receiving heat from a movable contact surface (e.g., contact surface segments 402-1, 402-2, 402-3, 402-4, 402-5) and allowing the flow of a vapor phase of the working fluid 412 to an external or remote condenser, a thermal management device 400 can allow liquid cold plate cooling to a heat-generating component or plurality of heat-generating components with a varying topography with only a single thermal management device.

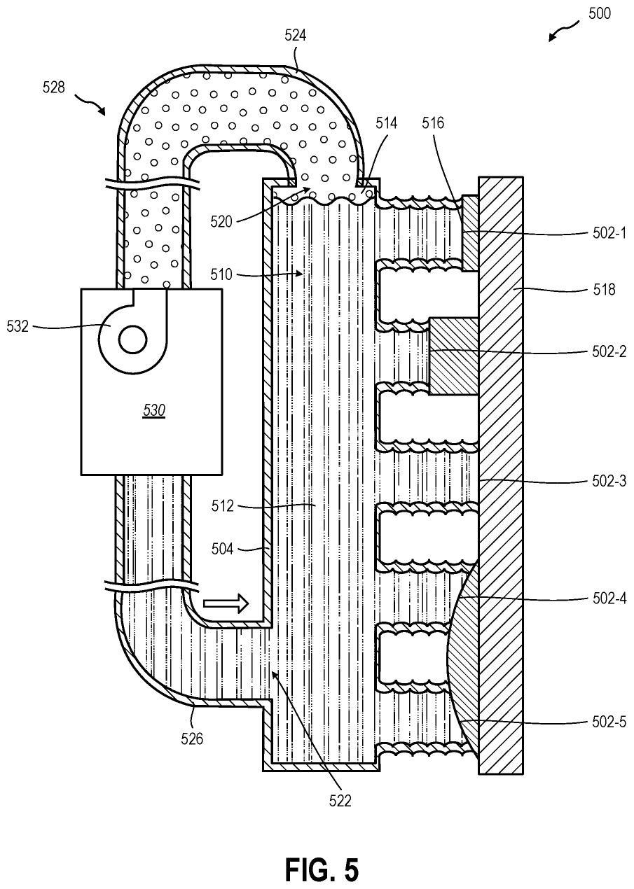

FIG. 5 is a side cross-sectional view of an embodiment of a thermal management system 528 including a thermal management device 500 in a vertical orientation relative to gravity. In some embodiments, when the thermal management device 500 is oriented vertically relative to gravity, the headspace 514 of the fluid reservoir 510 is reduced to a relatively small portion of the fluid reservoir 510 and/or to the outlet conduit 524. For example, the fluid reservoir 510 may be substantially filled with a liquid phase of the working fluid 512 to ensure the entire interior surface 516 of the contact surface (e.g., contact surface segments 502-1, 502-2, 502-3, 502-4, 502-5) is in contact with the liquid phase of the working fluid 512.

In some embodiments, at the working fluid 512 vaporizes, the vapor working fluid flows through the outlet port 520 of the heat sink body 504 and through the outlet conduit 524 to a condenser 530 or heat exchanger. The condenser 530 or heat exchanger may exhaust the heat to the ambient atmosphere or to another heat exhaustion system, such as a hot aisle or a liquid-cooling system in a datacenter. The condensate and/or cooled liquid phase of the working fluid 512 then flows through the inlet conduit 526 and through the inlet port 522 of the heat sink body 504.

In some embodiments, the condenser 530 or heat exchanger includes a fluid pump 532 therein to further urge the working fluid 512 to circulate through the outlet conduit 524 and the inlet conduit 526. In some embodiments, a fluid pump 532 is independent of the condenser 530 or heat exchanger but in communication with at least one of the conduits to urge the working fluid 512 to circulate through the conduits.

While embodiments described in relation to FIG. 1-1 through FIG. 5 include a movable contact surface comprising a plurality of contact surface segments, in some embodiments, the contact surface is or includes a flexible contact surface. In some embodiments, the flexible contact surface is a contact surface segment connected to a flexible support element, such as the contact surface segments 102-1, 102-2, 102-3, 102-4, 102-5 described in relation to FIG. 1-1 through FIG. 1-3. In some embodiments, a contact surface segment including a flexible contact surface allows the contact surface segment to conform to a curved or non-planar portion of a heat-generating component, such as the fourth contact surface segment 502-4 and fifth contact surface segment 502-5 conforming to a curved topography of the heat-generating component 518 illustrated in FIG. 5.

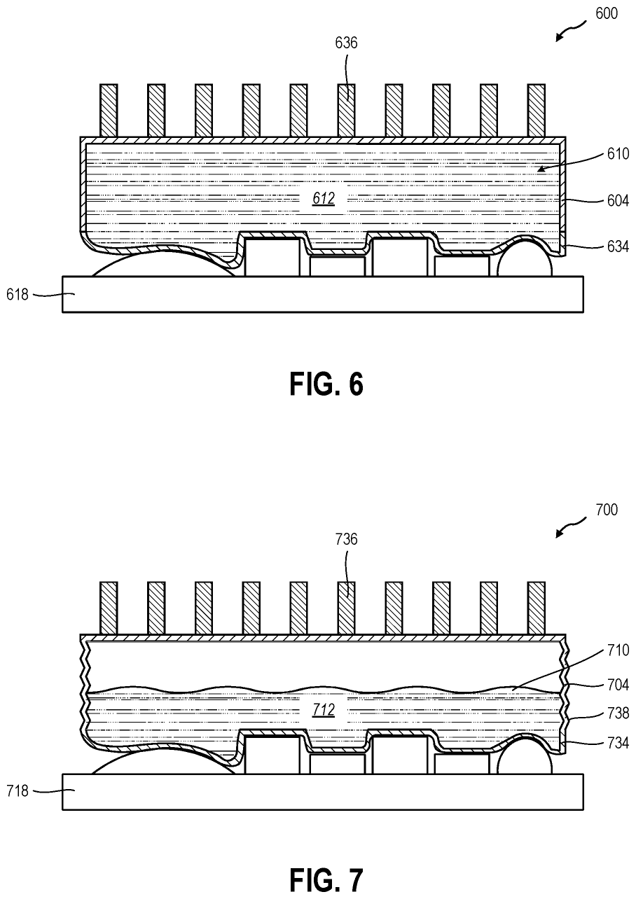

In some embodiments, the flexible contact surface is connected to the heat sink body without a flexible support element therebetween, such as illustrated in FIG. 6. In some embodiments, the heat sink body 604 and flexible contact surface 634 at least partially define a fluid reservoir 610 in which a working fluid 612 is positioned. The flexible contact surface 634, in some embodiments, includes a plastically and/or elastically deformable sheet of thermally conductive material that allows the working fluid 612 to receive heat from the heat-generating component(s) 618.

In some embodiments, the fluid reservoir 610 is substantially filled with a single-phase working fluid 612. The single-phase working fluid receives heat from the heat-generating component(s) 618 and transfers the heat (through conduction and/or convection) to the heat sink body 604. In some embodiments, the heat sink includes the heat sink body 604 and one or more thermal exhaustion features 636 on a surface thereof. In some embodiments, the thermal exhaustion features 636 include fins, rods, pins, surface treatments, coatings, etc., and combinations thereof that increase surface area, thermal transfer efficiency, or otherwise facilitate the exhaustion of heat from the heat sink. In some embodiments, the heat sink exhausts the heat to ambient atmosphere. In some embodiments, the heat sink exhausts the heat to another fluid, such as a hot aisle or a liquid cooling system in a datacenter.

While a single-phase working fluid 612 allows the fluid reservoir 610 to remain at a substantially constant volume during operation of the thermal management device 600 and heat-generating component(s) 618, in some embodiments, the thermal management device 600 includes a dual-phase working fluid 612. An elastically deformable flexible contact surface 634, in some embodiments, allows for changes in volume of fluid reservoir 610 as the dual-phase working fluid 612 vaporizes and condenses. In some embodiments, at least another surface (e.g., not the contact surface) of the heat sink or heat sink body is a flexible material, such as an elastic sheet or an elastically deformable bellows that allows the volume of the fluid reservoir 610 to change as the dual-phase working fluid 612 vaporizes and condenses.

FIG. 7 is a side cross-sectional view of an embodiment of a thermal management device 700 with an elastically deformable heat sink body 704 and a dual-phase working fluid 712 therein. In some embodiments, the vaporization of the working fluid 712 expands the working fluid 712. For example, at 1 atmosphere of pressure, liquid water is greater than 1000 times the density of water vapor at 100° C. This expansion can be at least partially compensated for by an elastically deformable heat sink body 704. In some embodiments, the heat sink body 704 includes bellows 738 or other elastically deformable elements that allow the interior volume of the heat sink body 704 and fluid reservoir 710 to change.

As the heat exhaustion features 736 conduct heat from the working fluid 712 and the heat sink body 704, the vapor phase of the working fluid 712 condenses and the pressure in the fluid reservoir 710 decreases, allowing the bellows 738 or other elastically deformable elements of the heat sink body 704 to decrease the volume of the fluid reservoir 710.

In some embodiments, the heat exhaustion features 736 coupled to the heat sink body 704 are compatible with any other embodiment of a thermal management device described herein, such as the embodiments of sealed thermal management devices described in relation to FIG. 1-1 through FIG. 2 or the embodiments of ported thermal management devices in fluid communication with a heat exchanger or condenser described in relation to FIG. 3 through FIG. 5. In some embodiments, the heat exhaustion features 736 are compatible with embodiments of thermal management devices including one or more contact surface segments movable relative to a heat sink body by flexible support elements, such as described in relation to FIG. 1-1 through FIG. 5.

In some embodiments, at least a portion of a contact surface includes a flexible contact surface, such as described in relation to FIGS. 6 and 7, and one or more contact surface segments movable relative to a heat sink body by flexible support elements such as described in relation to FIG. 1-1 through FIG. 5. As described herein, some embodiments of a movable contact surface include a flexible contact surface, such as described in relation to FIGS. 6 and 7, that is movable relative to a heat sink body by flexible support elements such as described in relation to FIG. 1-1 through FIG. 5.

As described herein, some embodiments of a thermal management device according to the present disclosure allows the use or reuse of a thermal management device with heat-generation components having non-planar surfaces.

### INDUSTRIAL APPLICABILITY

The present disclosure relates generally to systems and methods for thermal management of electronic devices or other heat-generating components. More particularly, embodiments according to the present disclosure relate to thermal management and thermal management devices for processors, hardware storage devices, application specific integrated circuits (ASICs), power supplies, system-on-chips (SOCs), networking devices, and other heat-generating components with non-planar surfaces. In an example, a SOC has multiple processors, memory devices, and electronic components facilitating communication between the processors and memory devices. The SOC may have a varying topography across the surfaces of the processors, memory devices, and other electronic components limiting the applicability of conventional heat sinks and thermal management devices.

In some embodiments, a thermal management device according to the present disclosure includes a contact surface configured to conform to a surface of the heat-generating component. The thermal management device includes a flexible contact surface, a plurality of independently moveable segments of the contact surface, or combinations thereof. In some embodiments, the thermal management device includes a plurality of contact surface segments that are independently movable relative to a heat sink. In some embodiments, at least one of the contact surface segments is coupled to a flexible heat transfer element to transfer heat from the contact surface segment to the heat sink of the thermal management device.

In some embodiments, the thermal management device includes a flexible contact surface that allows the contact surface to plastically and/or elastically deform to the topography of the heat-generating component(s) and receive heat from the plurality of surfaces of the heat-generating component(s). In some embodiments, the flexible contact surface includes or is made of a polymer or metal sheet, such as a mylar sheet. The flexible contact surface allows the contact surface to conform to a surface of the heat-generating component and receive heat from the heat-generating. In some embodiments, the flexible contact surface allows the contact surface to conform to a non-planar surface of the heat-generating component and/or a plurality of surfaces of the heat-generating component, providing thermal communication between a greater variety of heat-generating components and a heat sink of the thermal management device.

In some embodiments, the heat sink includes one or more heat exchange features. In some embodiments, a heat exchange feature includes a solid-state heat exchange feature that exhausts heat to ambient fluid, such as air. A solid-state heat exchange feature may include a fin, rod, pin, heat pipe, surface feature or coating, or other structure that increases surface area of the heat sink to more readily exhaust heat. In some embodiments, the heat exchange feature includes a reservoir or volume of working fluid that exhausts heat from the heat sink to ambient air. In some embodiments, the heat exchange feature includes a reservoir or volume of working fluid that is connected to an external heat exchanger through one or more fluid conduits. In some embodiments, the working fluid is a single-phase working fluid that remains in a single phase throughout the operation of the thermal management device (such as a liquid phase). In some embodiments, the working fluid is a dual-phase working fluid that vaporizes and condenses during operation of the thermal management device to transfer heat through the latent heat of boiling. In some embodiments, the working fluid is conveyed from a reservoir or other volume of the heat sink to an external heat exchanger that cools and/or condenses the working fluid before returning the working fluid to the reservoir or other volume of the heat sink.

In some embodiments, a thermal management device includes a plurality of contact surface segments that are independently movable relative to a heat sink body. In some embodiments, at least one contact surface segment is connected to the body by a flexible support element.

In some embodiments, the flexible support element is or includes a bellows. In some embodiments, the bellows is a metal bellows. In some embodiments, the bellows is a polymer bellows. In some embodiments, the flexible support element includes a plurality of convolutions that allow the flexible support element to extend or contract in a direction between the contact surface segment and the heat sink body. In some embodiments, the bellows includes edge-welded bellows. In some embodiments, the flexible support element allows the contact surface segment to change orientation relative to an initial position. For example, the flexible support element allows the contact surface segment to rotate relative to an initial position when the flexible support element elastically and/or plastically deforms.

In some embodiments, elastic deformation of the flexible support element allows the flexible support element to return or restore toward or to an original position for reuse of thermal management device. In some embodiments, elastic deformation can continue to provide a compressive force between the contact surface segment and the heat-generating component, ensuring a reliable thermal connection between the contact surface and the heat-generating component. For example, during use or transportation of the system of device containing the heat-generating component, the movement or vibrations of the heat-generating component and thermal management device relative to one another may introduce a gap between the contact surface and the heat-generating component. An elastically deformed flexible support element may apply a continuous compressive force to the contact surface segment to maintain the thermal connection.

In some embodiments, the plastic deformation of the flexible support element allows the flexible support element to retain a position of the contact surface segment upon removal of the thermal management device from the heat-generating component, for example, for maintenance, repair, or replacement of one or more components. In some embodiments, the plastic deformation of the flexible support element allows the contact surface segment to establish a thermal connection to the heat-generating component, and maintain that thermal connection, without continuous force applied to the heat-generating component. For example, plastic deformation allows the thermal management device to be applied to the heat-generating component at initial installation with only an initial application of force to the sensitive parts of the heat-generating component. In some embodiments, the flexible support element exhibits both plastic and elastic deformation during installation and use with the heat-generating component.

In some embodiments, the heat sink includes a fluid reservoir in the heat sink body. In some embodiments, the fluid reservoir has a working fluid therein. In some embodiments, the working fluid has a liquid phase in the fluid reservoir. In some embodiments, the working fluid has a vapor phase in the fluid reservoir. In some embodiments, the working fluid is positioned at least partially in the flexible support element. The working fluid receives heat from a heat-generating component through the contact surface (including the contact surface segments) to the heat sink body and/or through the thermal management device.

In some embodiments, the working fluid is a single-phase working fluid that remains in a single phase throughout the operation of the thermal management device (such as a liquid phase).

In some embodiments, the fluid reservoir includes a headspace in which a vapor phase of the working fluid or other gas is present. In some embodiments, the working fluid is a dual-phase working fluid that receives heat from the contact surface (e.g., the contact surface segments) and vaporizes to carry heat away from the contact surface into the fluid reservoir. In some embodiments, the latent heat of boiling allows the working fluid to absorb heat and vaporize without substantially increasing in temperature.

In some embodiments, the working fluid has a boiling temperature below a critical temperature at which the heat-generating components experience thermal damage. The working fluid can thereby receive heat from the heat-generating components to cool the heat-generating components before the heat-generating components experience damage.

For example, the heat-generating components may be computing components that experience damage above 100° Celsius (C). In some embodiments, the boiling temperature of the working fluid is less than a critical temperature of the heat-generating components. In some embodiments, the boiling temperature of the working fluid is less about 90° C. at 1 atmosphere of pressure. In some embodiments, the boiling temperature of the working fluid is less about 80° C. at 1 atmosphere of pressure. In some embodiments, the boiling temperature of the working fluid is less about 70° C. at 1 atmosphere of pressure. In some embodiments, the boiling temperature of the working fluid is less about 60° C. at 1 atmosphere of pressure. In some embodiments, the boiling temperature of the working fluid is at least about 35° C. at 1 atmosphere of pressure. In some embodiments, the working fluid includes water.

In some embodiments, the working fluid includes glycol. In some embodiments, the working fluid includes a combination of water and glycol. In some embodiments, the working fluid includes an aqueous solution. In some embodiments, the working fluid includes an electronic liquid, such as FC-72 available from 3M, or similar non-conductive fluids.

In some embodiments, an interior surface of the contact surface (e.g., the contact surface segments) and/or an interior surface of the flexible support element have nucleation sites thereon that promote the nucleation of vapor bubbles of the working fluid at or above the boiling temperature of the working fluid.

In some embodiments, the movement of the flexible support elements compresses the headspace and a compressible gas therein, which increases a pressure inside the headspace and the fluid reservoir. In some embodiments, movement of a first flexible support element relative to the heat sink body (e.g., compression that reduces an interior volume thereof) is at least partially compensated for by a movement of a second flexible support element relative to the heat sink body (e.g., extension that increases an interior volume thereof).

While some embodiments of a thermal management device including a single-phase working fluid have a headspace, a single-phase working fluid may not need a headspace, as the working fluid does not boil and increase pressure inside the fluid reservoir. In some embodiments, without a headspace in the fluid reservoir and/or when the fluid reservoir is substantially filled with a liquid phase of the working fluid, the thermal management device is operably in any orientation relative to gravity without a portion of the contact surface (e.g., contact surface segments) not contacting the liquid phase of the working fluid. While a vapor phase of the working fluid or other gas in the fluid reservoir may receive and/or conduct heat from the contact surface, a liquid phase or liquid working fluid absorbs heat from the contact surface more efficiently.

While the embodiments described herein include a sealed fluid reservoir in the heat sink body and the flexible support elements, in some embodiments, the heat sink body includes one or more ports to flow at least a portion of the working fluid from the fluid reservoir to an external heat exchanger or condenser. In some embodiments, a thermal management device includes a heat sink body with an outlet port and an inlet port that allow fluid communication out of and into the fluid reservoir, respectively. In some embodiments, a single port allows movement of the working fluid in and out of the fluid reservoir.

In some embodiments, the outlet port is connected to an outlet conduit that allows fluid flow therethrough to a heat exchanger to exhaust heat from the single-phase working fluid. In some embodiments, the inlet port is connected on an inlet conduit that allows fluid flow therethrough from a heat exchanger to return cooled single-phase working fluid to the fluid reservoir. By receiving heat from a movable contact surface (e.g., contact surface segments) and allowing the flow of hot working fluid to an external or remote heat exchanger, a thermal management device can allow liquid cold plate cooling to a heat-generating component or plurality of heat-generating components with a varying topography with only a single thermal management device.

In some embodiments, a thermal management device includes a heat sink body with an outlet port and an inlet port that allow fluid communication out of and into the fluid reservoir, respectively. In some embodiments, a single port allows movement of the working fluid in and out of the fluid reservoir.

In some embodiments, the outlet port is connected to an outlet conduit that allows a vapor phase of the working fluid to flow therethrough to a condenser to exhaust heat from the dual-phase working fluid. In some embodiments, the inlet port is connected on an inlet conduit that allows flow of a condensate of the working fluid therethrough from the condenser to return the liquid phase of the working fluid to the fluid reservoir. By receiving heat from a movable contact surface (e.g., contact surface segments) and allowing the flow of a vapor phase of the working fluid to an external or remote condenser, a thermal management device can allow liquid cold plate cooling to a heat-generating component or plurality of heat-generating components with a varying topography with only a single thermal management device.

In some embodiments, when the thermal management device is oriented vertically relative to gravity, the headspace of the fluid reservoir is reduced to a relatively small portion of the fluid reservoir and/or to the outlet conduit. For example, the fluid reservoir may be substantially filled with a liquid phase of the working fluid to ensure the entire interior surface of the contact surface (e.g., contact surface segments) is in contact with the liquid phase of the working fluid.

In some embodiments, at the working fluid vaporizes, the vapor working fluid flows through the outlet port of the heat sink body and through the outlet conduit to a condenser or heat exchanger. The condenser or heat exchanger may exhaust the heat to the ambient atmosphere or to another heat exhaustion system, such as a hot aisle or a liquid-cooling system in a datacenter. The condensate and/or cooled liquid phase of the working fluid then flows through the inlet conduit and through the inlet port of the heat sink body.

In some embodiments, the condenser or heat exchanger includes a fluid pump therein to further urge the working fluid to circulate through the outlet conduit and the inlet conduit. In some embodiments, a fluid pump is independent of the condenser or heat exchanger but in communication with at least one of the conduits to urge the working fluid to circulate through the conduits.

While embodiments described herein include a movable contact surface comprising a plurality of contact surface segments, in some embodiments, the contact surface is or includes a flexible contact surface. In some embodiments, the flexible contact surface is a contact surface segment connected to a flexible support element. In some embodiments, a contact surface segment including a flexible contact surface allows the contact surface segment to conform to a curved or non-planar portion of a heat-generating component.

In some embodiments, the flexible contact surface is connected to the heat sink body without a flexible support element therebetween. In some embodiments, the heat sink body and flexible contact surface at least partially define a fluid reservoir in which a working fluid is positioned. The flexible contact surface, in some embodiments, includes a plastically and/or elastically deformable sheet of thermally conductive material that allows the working fluid to receive heat from the heat-generating component(s).

In some embodiments, the fluid reservoir is substantially filled with a single-phase working fluid. The single-phase working fluid receives heat from the heat-generating component(s) and transfers the heat (through conduction and/or convection) to the heat sink body. In some embodiments, the heat sink includes the heat sink body and one or more thermal exhaustion features on a surface thereof. In some embodiments, the thermal exhaustion features include fins, rods, pins, surface treatments, coatings, etc., and combinations thereof that increase surface area, thermal transfer efficiency, or otherwise facilitate the exhaustion of heat from the heat sink. In some embodiments, the heat sink exhausts the heat to ambient atmosphere. In some embodiments, the heat sink exhausts the heat to another fluid, such as a hot aisle or a liquid cooling system in a datacenter.

While a single-phase working fluid allows the fluid reservoir to remain at a substantially constant volume during operation of the thermal management device and heat-generating component(s), in some embodiments, the thermal management device includes a dual-phase working fluid. An elastically deformable flexible contact surface, in some embodiments, allows for changes in volume of fluid reservoir as the dual-phase working fluid vaporizes and condenses. In some embodiments, at least another surface (e.g., not the contact surface) of the heat sink or heat sink body is a flexible material, such as an elastic sheet or an elastically deformable bellows that allows the volume of the fluid reservoir to change as the dual-phase working fluid vaporizes and condenses.

In some embodiments, the vaporization of the working fluid expands the working fluid. This expansion can be at least partially compensated for by an elastically deformable heat sink body. In some embodiments, the heat sink body includes bellows or other elastically deformable elements that allow the interior volume of the heat sink body and fluid reservoir to change.

As the heat exhaustion features conduct heat from the working fluid and the heat sink body, the vapor phase of the working fluid condenses and the pressure in the fluid reservoir decreases, allowing the bellows or other elastically deformable elements of the heat sink body to decrease the volume of the fluid reservoir.

In some embodiments, the heat exhaustion features coupled to the heat sink body are compatible with any other embodiment of a thermal management device described herein, such as the embodiments of sealed thermal management devices or the embodiments of ported thermal management devices in fluid communication with a heat exchanger or condenser. In some embodiments, the heat exhaustion features are compatible with embodiments of thermal management devices including one or more contact surface segments movable relative to a heat sink body by flexible support elements.

In some embodiments, at least a portion of a contact surface includes a flexible contact surface and one or more contact surface segments movable relative to a heat sink body by flexible support elements. As described herein, some embodiments of a movable contact surface include a flexible contact surface, that is movable relative to a heat sink body by flexible support elements.

The present disclosure relates to systems and methods for cooling electronic components and/or devices according to at least the examples provided in the sections below:

Clause 1. A thermal management device, comprising: a heat sink body defining a fluid reservoir; a working fluid in the fluid reservoir; and a movable contact surface configured to transfer heat from a heat-generating component to the working fluid, wherein at least a portion of the movable contact surface is movable relative to the heat sink body.

Clause 2. The thermal management device of clause 1, wherein the movable contact surface includes a plurality of contact surface segments.

Clause 3. The thermal management device of clause 2, wherein at least one contact surface segment of the plurality of contact surface segments is connected to the heat sink body by a flexible support element.

Clause 4. The thermal management device of clause 3, wherein the flexible support element is a bellows having a plurality of convolutions.

Clause 5. The thermal management device of clause 3, wherein the flexible support element allows rotation of the at least one contact surface segment relative to the heat sink body.

Clause 6. The thermal management device of clause 3, wherein at least one contact surface segment of the plurality of contact surface segments includes a flexible contact surface.

Clause 7. The thermal management device of clause 1, wherein the movable contact surface includes a flexible contact surface.

Clause 8. The thermal management device of clause 6, wherein the flexible contact surface includes an elastically deformable polymer.

Clause 9. The thermal management device of clause 6, wherein the flexible contact surface includes an elastically deformable metal.

Clause 10. The thermal management device of clause 1, further comprising a headspace in the fluid reservoir with a compressible gas positioned therein.

Clause 11. The thermal management device of clause 1, further comprising at least one heat exhaustion feature coupled to the heat sink body.

Clause 12. The thermal management device of clause 1, further comprising at least one port in the heat sink body configured to allow fluid communication into and out of the fluid reservoir.

Clause 13. The thermal management device of clause 1, wherein at least a portion of the heat sink body is elastically deformable to change a volume of the fluid reservoir.

Clause 14. A thermal management system comprising: a thermal management device including: a heat sink body defining a fluid reservoir, a single-phase working fluid in the fluid reservoir, and a movable contact surface configured to transfer heat from a heat-generating component to the single-phase working fluid, wherein at least a portion of the movable contact surface is movable relative to the heat sink body; and a heat exchanger in fluid communication with the fluid reservoir and configured to exhaust heat from the single-phase working fluid.

Clause 15. The thermal management system of clause 14, further comprising a fluid pump in communication with the single-phase working fluid to circulate the single-phase working fluid.

Clause 16. The thermal management system of clause 14, further comprising: an outlet conduit connected to an outlet port of the heat sink body and providing fluid communication between the fluid reservoir and the heat exchanger; and an inlet conduit connected to an inlet port of the heat sink body and providing fluid communication between the fluid reservoir and the heat exchanger.

Clause 17. A thermal management system comprising: a thermal management device including: a heat sink body defining a fluid reservoir, a dual-phase working fluid in the fluid reservoir, and a movable contact surface configured to transfer heat from a heat-generating component to the dual-phase working fluid, wherein at least a portion of the movable contact surface is movable relative to the heat sink body; and a condenser in fluid communication with the fluid reservoir and configured to exhaust heat from the dual-phase working fluid.

Clause 18. The thermal management system of clause 17, wherein at least a portion of the heat sink body is elastically deformable.

Clause 19. The thermal management system of clause 17, an outlet conduit connected to an outlet port of the heat sink body and providing fluid communication between the fluid reservoir and the condenser; and an inlet conduit connected to an inlet port of the heat sink body and providing fluid communication between the fluid reservoir and the condenser.

Clause 20. The thermal management system of clause 17, wherein a liquid phase of the fluid reservoir substantially fills the fluid reservoir.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about”, “substantially”, or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A thermal management device, comprising:
a heat sink body defining a fluid reservoir;
a working fluid in the fluid reservoir; and
a movable contact surface configured to transfer heat from a heat-generating component to the working fluid, wherein at least a portion of the movable contact surface is movable relative to the heat sink body.

2. The thermal management device of claim 1, wherein the movable contact surface includes a plurality of contact surface segments.

3. The thermal management device of claim 2, wherein at least one contact surface segment of the plurality of contact surface segments is connected to the heat sink body by a flexible support element.

4. The thermal management device of claim 3, wherein the flexible support element is a bellows having a plurality of convolutions.

5. The thermal management device of claim 3, wherein the flexible support element allows rotation of the at least one contact surface segment relative to the heat sink body.

6. The thermal management device of claim 3, wherein at least one contact surface segment of the plurality of contact surface segments includes a flexible contact surface.

7. The thermal management device of claim 1, wherein the movable contact surface includes a flexible contact surface.

8. The thermal management device of claim 6, wherein the flexible contact surface includes an elastically deformable polymer.

9. The thermal management device of claim 6, wherein the flexible contact surface includes an elastically deformable metal.

10. The thermal management device of claim 1, further comprising a headspace in the fluid reservoir with a compressible gas positioned therein.

11. The thermal management device of claim 1, further comprising at least one heat exhaustion feature coupled to the heat sink body.

12. The thermal management device of claim 1, further comprising at least one port in the heat sink body configured to allow fluid communication into and out of the fluid reservoir.

13. The thermal management device of claim 1, wherein at least a portion of the heat sink body is elastically deformable to change a volume of the fluid reservoir.

14. A thermal management system comprising:
a thermal management device including:
a heat sink body defining a fluid reservoir,
a single-phase working fluid in the fluid reservoir, and
a movable contact surface configured to transfer heat from a heat-generating component to the single-phase working fluid, wherein at least a portion of the movable contact surface is movable relative to the heat sink body; and
a heat exchanger in fluid communication with the fluid reservoir and configured to exhaust heat from the single-phase working fluid.

15. The thermal management system of claim 14, further comprising a fluid pump in communication with the single-phase working fluid to circulate the single-phase working fluid.

16. The thermal management system of claim 14, further comprising:
an outlet conduit connected to an outlet port of the heat sink body and providing fluid communication between the fluid reservoir and the heat exchanger; and
an inlet conduit connected to an inlet port of the heat sink body and providing fluid communication between the fluid reservoir and the heat exchanger.

17. A thermal management system comprising:
a thermal management device including:
a heat sink body defining a fluid reservoir,
a dual-phase working fluid in the fluid reservoir, and
a movable contact surface configured to transfer heat from a heat-generating component to the dual-phase working fluid, wherein at least a portion of the movable contact surface is movable relative to the heat sink body; and
a condenser in fluid communication with the fluid reservoir and configured to exhaust heat from the dual-phase working fluid.

18. The thermal management system of claim 17, wherein at least a portion of the heat sink body is elastically deformable.

19. The thermal management system of claim 17,
an outlet conduit connected to an outlet port of the heat sink body and providing fluid communication between the fluid reservoir and the condenser; and
an inlet conduit connected to an inlet port of the heat sink body and providing fluid communication between the fluid reservoir and the condenser.

20. The thermal management system of claim 17, wherein a liquid phase of the fluid reservoir substantially fills the fluid reservoir.
